(19) United States
(12) Patent Application Publication
(10) Pub. No.: US 2021/0358995 A1
(43) Pub. Date: Nov. 18, 2021

(54) RADIATION DETECTOR

(71) Applicant: CANON ELECTRON TUBES & DEVICES CO., LTD., Otawara-shi (JP)

(72) Inventors: Shuichi FUJITA, Nasushiobara (JP); Yuma SAKAMOTO, Otawara (JP)

(73) Assignee: CANON ELECTRON TUBES & DEVICES CO., LTD., Otawara-shi (JP)

(21) Appl. No.: 17/160,452

(22) Filed: Jan. 28, 2021

(30) Foreign Application Priority Data
May 15, 2020 (JP) 2020-085820
May 15, 2020 (JP) 2020-085829

(51) Int. Cl. H01L 27/146; G01T 1/24; G01T 1/20

(52) U.S. Cl. CPC H01L 27/14658; G01T 1/247; G01T 1/2002; G01T 1/2018; H01L 27/14603

(57) ABSTRACT

A radiation detector according to an embodiment includes: control lines; data lines; detecting parts; a gate drive circuit; a signal detection circuit; a radiation incidence determination circuit; and a controller controlling the gate drive circuit and the signal detection circuit. The controller performs the control by dividing the control lines into a first group and a second group, the radiation incidence determination circuit determines the incidence start of the radiation based on a value of the image data read from the detecting part electrically connected to the control line included in the first group. Or, the controller performs the control by dividing the data lines into a third group and a fourth group, the radiation incidence determination circuit determines the incidence start of the radiation based on a value of the image data read from the detecting part electrically connected to the data line included in the third group.

### CROSS-REFERENCE TO RELATED APPLICATIONS

This application is based upon and claims the benefit of priority from Japanese Patent Application No. 2020-085820, filed on May 15, 2020, and Japanese Patent Application No. 2020-085829, filed on May 15, 2020; the entire contents of which are incorporated herein by reference.

### FIELD

Embodiments of the invention relate to a radiation detector.

### BACKGROUND

An X-ray detector is an example of a radiation detector. The X-ray detector includes, for example, an array substrate that includes multiple photoelectric converters, and a scintillator that is provided on the multiple photoelectric converters and converts X-rays into fluorescence. The photoelectric converter includes a photoelectric conversion element that converts the fluorescence from the scintillator into charge, a thin film transistor that switches between storing and discharging the charge, a storage capacitor that stores the charge, etc.

Generally, an X-ray detector reads image data as follows. First, the incidence of the X-rays is recognized from a signal input from the outside. Then, after a predetermined amount of time has elapsed, the thin film transistors of the photoelectric converters performing the reading are set to the ON-state, and the stored charge is read as image data. However, such an X-ray detector requires a synchronous interface for synchronizing the X-ray detector with external devices such as an X-ray source, etc.

Here, the values of the image data obtained by the scintillator and the photoelectric conversion element are different between when the X-rays are incident and when the X-rays are not incident. Therefore, technology has been proposed in which the incidence start of the X-rays is detected by detecting the difference between the values of the image data when the X-rays are not incident and the values of the image data when the X-rays are incident. However, such an X-ray detector requires an imaging preparation stage of pre-acquiring and storing image data when the X-rays are not incident as a base of comparison, and constantly fetching the image data and performing a comparison calculation.

Therefore, electrical power is constantly consumed even in standby when X-rays are not incident, and the power consumption is undesirably large. In such a case, it is difficult to use a portable X-ray detector having a battery as the power supply for a long period of time because the consumption of the battery increases. Also, the temperature of the circuit easily increases due to the large power consumption, and there are cases where the use of the X-ray detector is limited in a high-temperature environment. Large-capacity image memory is necessary to store the comparison image.

Therefore, it is desirable to develop a radiation detector in which the power consumption when detecting the incidence of radiation can be suppressed.

### BRIEF DESCRIPTION OF THE DRAWINGS

FIG. 1 is a schematic perspective view for illustrating an X-ray detector according to an embodiment;

FIG. 2 is a circuit diagram of an array substrate;

FIG. 3 is a block diagram of an X-ray detector;

FIG. 4 is a sequence diagram for illustrating the reading of image data;

FIG. 5 is a timing chart for illustrating the reading of the image data;

FIG. 6 is an internal equivalent circuit of an acquisition operation of an X-ray image;

FIG. 7 is a block diagram for illustrating an X-ray incidence determination circuit;

FIG. 8 is a schematic view for illustrating an “incidence detection region”;

FIG. 9 is an equivalent circuit considering the switching of the reading;

FIG. 10 is a sequence diagram for illustrating the switching of the reading of the image data;

FIG. 11 is a timing chart for illustrating the reading of the image data from the “incidence detection region”;

FIG. 12 is a schematic view for illustrating patterns of changes of the values of the image data;

FIG. 13 is a timing chart for illustrating the reading of the image data from the “region in which the X-ray image is acquired”;

FIG. 14 is a schematic view for illustrating the “incidence detection region”;

FIG. 15 is a sequence diagram for illustrating the switching of the reading of the image data;

FIG. 16 is a timing chart for illustrating the reading of the image data from the “incidence detection region”;

FIGS. 17A and 17B are schematic views for illustrating the relationship between the position of a subject and the “incidence detection region”;

FIG. 18 is a schematic view for illustrating patterns of changes of the values of the image data; and

FIG. 19 is a timing chart for illustrating the reading of the image data from the “region in which the X-ray image is acquired”.

### DETAILED DESCRIPTION

A radiation detector according to an embodiment includes: multiple control lines extending in a first direction to be arranged in a second direction crossing the first direction; multiple data lines extending in the second direction to be arranged in the first direction; multiple detecting parts detecting radiation directly or in collaboration with a scintillator, each including a thin film transistor electrically connected to a corresponding control line and a corresponding data line; a gate drive circuit switching between an ON-state and an OFF-state of the thin film transistors; a signal detection circuit reading image data from the detecting parts when the thin film transistors are in the ON-state; a radiation incidence determination circuit determining an incidence start of the radiation based on a value of the read image data; and a controller controlling the gate drive circuit and the signal detection circuit.

The controller performs the control by dividing the multiple control lines into a first group and a second group next to the first group in the second direction, and the radiation incidence determination circuit determines the incidence start of the radiation based on a value of the image data read from the detecting part electrically connected to the control line included in the first group.

Or, the controller performs the control by dividing the multiple data lines into a third group and a fourth group next to the third group in the first direction, and the radiation incidence determination circuit determines the incidence start of the radiation based on a value of the image data read from the detecting part electrically connected to the data line included in the third group.

Examples of embodiments will now be described with reference to the drawings. Similar components in the drawings are marked with the same reference numerals, and a detailed description is omitted as appropriate.

A radiation detector according to the embodiment is applicable to various radiation such as y-rays, etc., as well as X-rays. Here, as an example, X-rays are described as a typical example of radiation. Accordingly, applications to other radiation also are possible by replacing “X-ray” of the embodiments described below with “other radiation”.

An X-ray detector 1 illustrated below is an X-ray planar sensor that detects an X-ray image, which is a radiation image. X-ray planar sensors can be largely divided into direct conversion and indirect conversion.

In direct conversion, photoconductive charge (charge) that is generated in a photoconductive film interior by incident X-rays is directly guided by a high electric field to a storage capacitor for charge storage. Known technology is applicable to the detecting part of a direct conversion X-ray detector, and a detailed description is therefore omitted.

In indirect conversion, the X-rays are converted into fluorescence (visible light) by a scintillator; the fluorescence is converted into charge by a photoelectric conversion element such as a photodiode, etc.; and the charge is guided to a storage capacitor.

Although the indirect conversion X-ray detector 1 is illustrated as an example hereinbelow, the invention is applicable also to a direct conversion X-ray detector.

In other words, it is sufficient for the X-ray detector to include a detecting part that converts X-rays into electrical information. For example, the detecting part can detect the X-rays directly or in collaboration with a scintillator.

For example, the X-ray detector 1 can be used in general medical care, etc. However, the applications of the X-ray detector 1 are not limited to general medical care and the like.

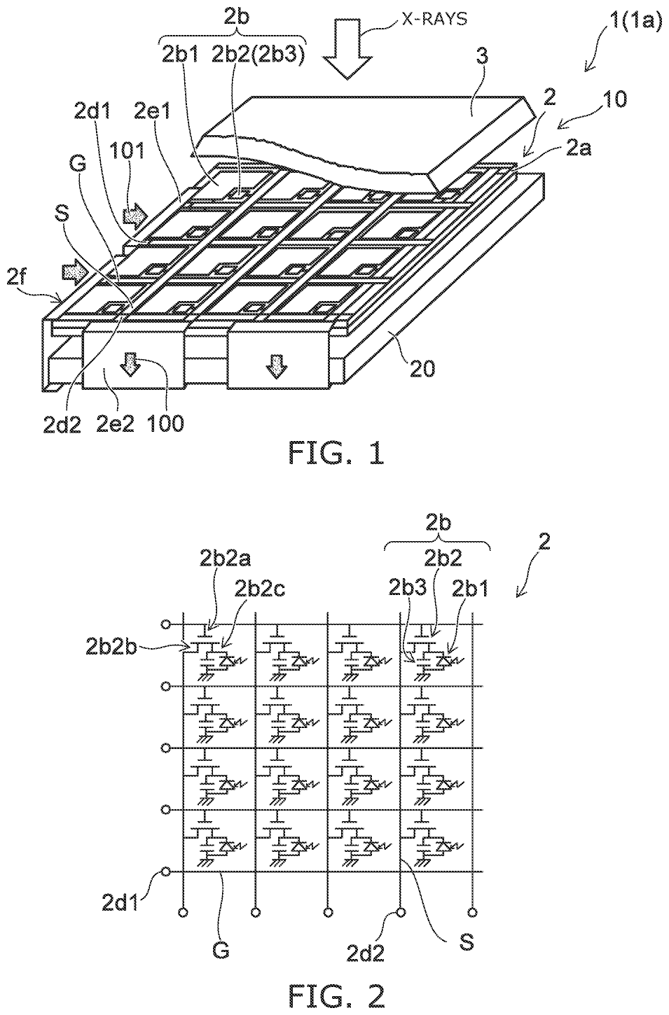

FIG. 1 is a schematic perspective view for illustrating the X-ray detector 1 according to the embodiment.

FIG. 2 is a circuit diagram of an array substrate 2.

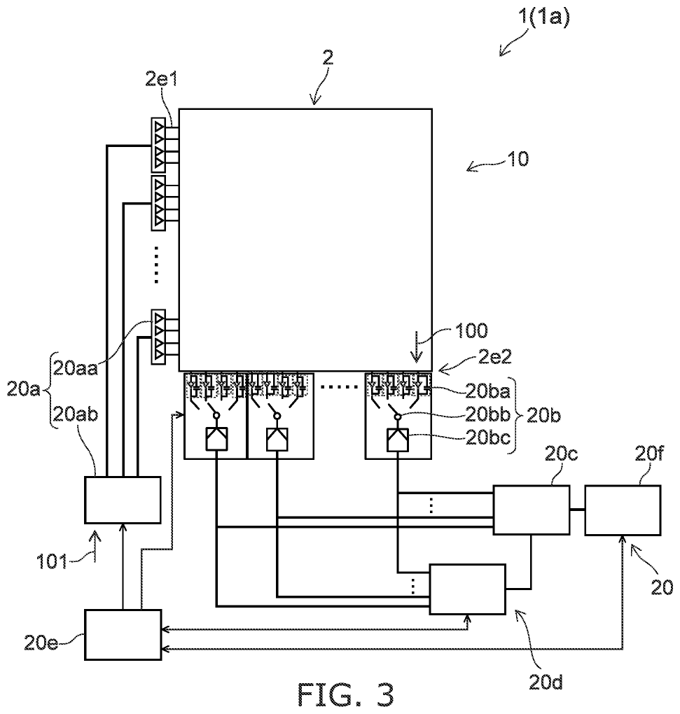

FIG. 3 is a block diagram of the X-ray detector 1.

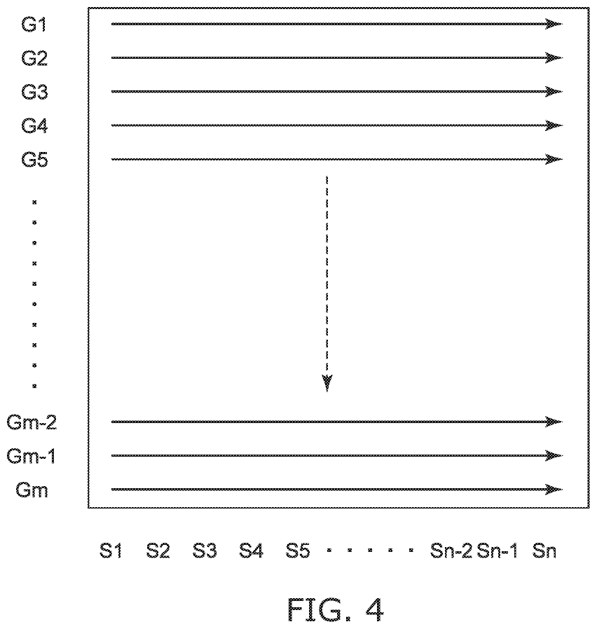

FIG. 4 is a sequence diagram for illustrating the reading of image data 100.

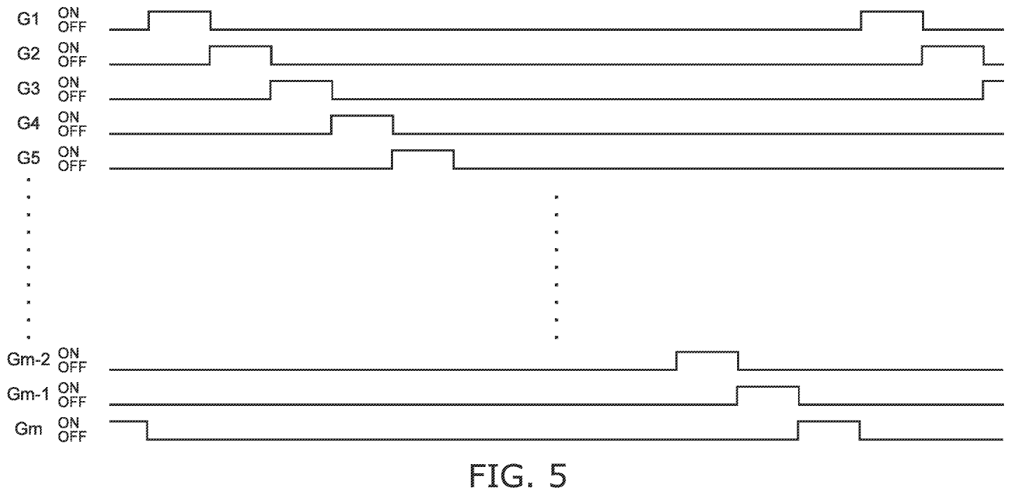

FIG. 5 is a timing chart for illustrating the reading of the image data 100.

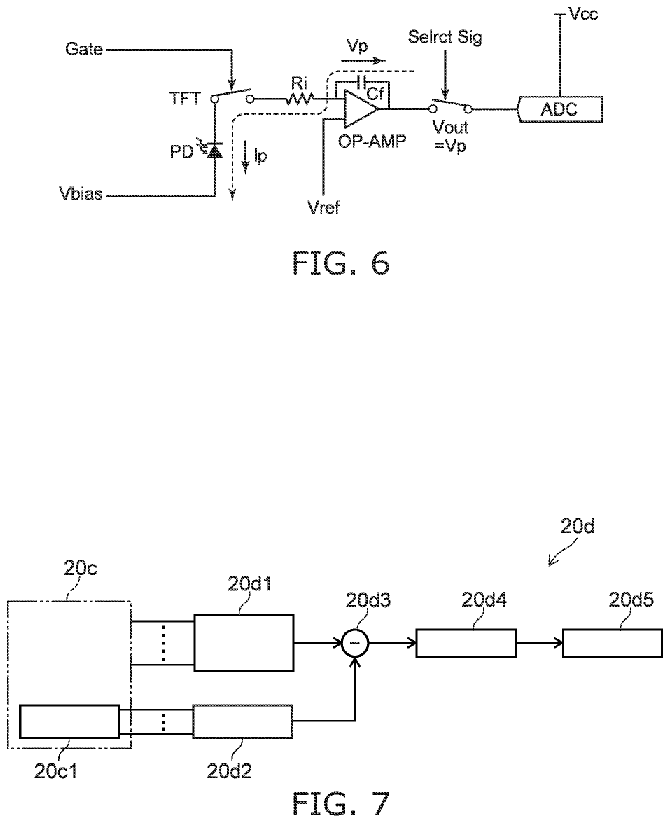

FIG. 6 is an internal equivalent circuit of an acquisition operation of an X-ray image.

As shown in FIGS. 1 to 3, an X-ray detection module 10 and a circuit board 20 can be provided in the X-ray detector 1. A not-illustrated housing also can be provided in the X-ray detector 1. The X-ray detection module 10 and the circuit board 20 can be located inside the housing. For example, a plate-shaped support plate can be provided inside the housing, the X-ray detection module 10 can be located at the surface of the support plate at the X-ray incident side, and the circuit board 20 can be located at the surface of the support plate at the side opposite to the X-ray incident side.

The array substrate 2 and a scintillator 3 can be provided in the X-ray detection module 10. The array substrate 2 can include a substrate 2a, a photoelectric converter 2b, a control line (or gate line) G, a data line (or signal line) S, an interconnect pad 2d1, an interconnect pad 2d2, and a protective layer 2f. The numbers of the photoelectric converters 2b, the control lines G, the data lines S, etc., are not limited to those illustrated.

In the X-ray detector 1 according to the embodiment, the photoelectric converter 2b is a detecting part that detects X-rays in collaboration with the scintillator 3.

The substrate 2a can have a plate shape and can be formed from glass such as alkali-free glass, etc. The planar shape of the substrate 2a can be rectangular.

Multiple photoelectric converters 2b can be provided at one surface side of the substrate 2a. The photoelectric converters 2b can be located in regions defined by the control lines G and the data lines S. The multiple photoelectric converters 2b can be arranged in a matrix configuration. For example, one photoelectric converter 2b corresponds to one pixel of an X-ray image.

A thin film transistor (TFT) 2b2, which is a switching element, and a photoelectric conversion element 2b1 can be provided in each of the multiple photoelectric converters 2b. A storage capacitor 2b3 that stores a signal charge converted by the photoelectric conversion element 2b1 also can be provided. For example, the storage capacitor 2b3 can have a flat plate shape and can be located under each thin film transistor 2b2. However, according to the capacitance of the photoelectric conversion element 2b1, the photoelectric conversion element 2b1 also can be used as the storage capacitor 2b3.

The photoelectric conversion element 2b1 can be, for example, a photodiode or the like.

The thin film transistor 2b2 can switch between storing and discharging the charge of the storage capacitor 2b3. The thin film transistor 2b2 can include a gate electrode 2b2a, a drain electrode 2b2b, and a source electrode 2b2c. The gate electrode 2b2a of the thin film transistor 2b2 can be electrically connected to a corresponding control line G. The drain electrode 2b2b of the thin film transistor 2b2 can be electrically connected to a corresponding data line S. The source electrode 2b2c of the thin film transistor 2b2 can be electrically connected to a corresponding photoelectric conversion element 2b1 and a corresponding storage capacitor 2b3. The storage capacitor 2b3 and the anode side of the photoelectric conversion element 2b1 can be electrically connected to ground. Or, the storage capacitor 2b3 and the anode side of the photoelectric conversion element 2b1 can be electrically connected to a not-illustrated bias line.

Multiple control lines G can be arranged parallel to each other at a prescribed spacing. For example, the multiple control lines G extend in a row direction (corresponding to an example of a first direction) and are arranged in a column direction (corresponding to an example of a second direction) crossing the row direction. One control line G can be electrically connected to one of the multiple interconnect pads 2d1 located at the peripheral edge vicinity of the substrate 2a. One of multiple interconnects provided in a flexible printed circuit board 2e1 can be electrically connected to one interconnect pad 2d1. The other ends of the multiple interconnects of the flexible printed circuit board 2e1 each can be electrically connected to a gate drive circuit 20a provided in the circuit board 20.

Multiple data lines S can be arranged parallel to each other at a prescribed spacing. For example, the data lines S extend in the column direction and are arranged in the row direction. The one data line S can be electrically connected to one of the multiple interconnect pads 2d2 located at the peripheral edge vicinity of the substrate 2a. One interconnect pad 2d2 can be electrically connected to one of multiple interconnects provided in a flexible printed circuit board 2e2. The other ends of the multiple interconnects of the flexible printed circuit board 2e2 each can be electrically connected to a signal detection circuit 20b provided in the circuit board 20.

For example, the control line G and the data line S can be formed using a low-resistance metal such as aluminum, chrome, etc.

The protective layer 2f can cover the photoelectric converters 2b, the control lines G, and the data lines S. The protective layer 2f can be formed from an insulating material.

The scintillator 3 can be provided on the multiple photoelectric converters 2b. The scintillator 3 can convert the incident X-rays into fluorescence. The scintillator 3 can cover the region (the effective pixel region) in which the multiple photoelectric converters 2b are located. For example, the scintillator 3 can be formed using cesium iodide (CsI):thallium (TI), sodium iodide (NaI):thallium (TI), cesium bromide (CsBr):europium (Eu), etc. The scintillator 3 can be formed using vacuum vapor deposition. By forming the scintillator 3 with vacuum vapor deposition, the scintillator 3 can be made of an aggregate of multiple columnar crystals.

For example, the scintillator 3 also can be formed using terbium-activated sulfated gadolinium (Gd₂O₂S/Tb or GOS), etc. In such a case, a trench can be provided in a matrix configuration so that a rectangular-prism-shaped scintillator 3 is provided for each of the multiple photoelectric converters 2b.

A reflective layer can be provided at the X-ray incident side of the scintillator 3. The fluorescence that is generated by the scintillator 3 and travels toward the side opposite to where the photoelectric converters 2b are located is reflected by the reflective layer toward the photoelectric converters 2b.

A moisture-resistant part that covers the scintillator 3 and the reflective layer also can be provided.

The circuit board 20 can be located at the side of the array substrate 2 opposite to where the scintillator 3 is located. The circuit board 20 can be electrically connected to the X-ray detection module 10 (the array substrate 2).

As shown in FIG. 3, the gate drive circuit 20a, the signal detection circuit 20b, memory 20c, an X-ray incidence determination circuit 20d, a controller 20e, and an image configuration circuit 20f can be provided in the circuit board 20. These components can be provided in one substrate or can be provided separately in multiple substrates.

The gate drive circuit 20a can switch between an ON-state and an OFF-state of the thin film transistors 2b2. The gate drive circuit 20a can include a row selection circuit 20ab and multiple gate drivers 20aa.

A control signal 101 can be input from the controller 20e to the row selection circuit 20ab. The row selection circuit 20ab can input the control signal 101 to the corresponding gate driver 20aa according to the scan direction of the X-ray image.

The gate driver 20aa can input the control signal 101 to the corresponding control line G.

For example, as shown in FIGS. 4 and 5, the gate drive circuit 20a can sequentially input the control signal 101 to the control lines G1 to Gm via the flexible printed circuit board 2e1. The thin film transistors 2b2 are set to the ON-state by the control signals 101 input to the control lines G, and the charge (the image data 100) can be read from the storage capacitors 2b3.

The signal detection circuit 20b can read the image data 100 from the photoelectric converters 2b when the thin film transistors 2b2 are in the ON-state. The signal detection circuit 20b can include multiple integrating amplifiers 20ba, multiple selection circuits 20bb, and multiple AD converters 20bc.

One integrating amplifier 20ba can be electrically connected to one data line S. The integrating amplifiers 20ba can sequentially receive the image data 100 from the photoelectric converters 2b. Then, the integrating amplifier 20ba can integrate the current flowing in a constant amount of time and can output a voltage corresponding to the integral to the selection circuit 20bb. Thus, the value (the charge amount) of the current flowing through the data line S within a prescribed period of time can be converted into a voltage value. In other words, the integrating amplifier 20ba can convert image data information corresponding to the intensity distribution of the fluorescence generated by the scintillator 3 into potential information.

The selection circuit 20bb can sequentially read the image data 100 converted into the potential information by selecting the integrating amplifier 20ba that performs the reading.

The AD converter 20bc can sequentially convert the read image data 100 into a digital signal. The image data 100 that is converted into the digital signal can be stored in the memory 20c.

For example, the signal detection circuit 20b can sequentially read the image data 100 for each of the data lines S1 to Sn via the flexible printed circuit board 2e2.

An internal equivalent circuit of such an acquisition operation of the X-ray image is as illustrated in FIG. 6. FIGS. 4 and 6 are when simply reading the image data 100 and do not consider the switching between the reading of the image data 100 from the “incidence detection region” and the reading of the image data 100 from the “region in which the X-ray image is acquired”, which is described below.

For example, the memory 20c can store a control program that controls the circuits of the circuit board 20. For example, the memory 20c also can store data such as thresholds necessary when executing the control program, etc. The memory 20c also can temporarily store the image data 100 that is converted into the digital signals.

The memory 20c can include a comparison data memory 20c1 that stores “comparison data” that is used when the X-ray incidence determination circuit 20d determines the incidence start of the X-rays (referring to FIG. 7). The “comparison data” can be, for example, image data 100 read directly before the image data 100 to be used as the determination object.

The X-ray incidence determination circuit 20d can determine the incidence start of the X-rays based on a value of the image data 100 that is read when the thin film transistor 2b2 is in the ON-state.

FIG. 7 is a block diagram for illustrating the X-ray incidence determination circuit 20d.

As shown in FIG. 7, the X-ray incidence determination circuit 20d can include a selector 20d1, a selector 20d2, a subtractor circuit 20d3, a comparison circuit 20d4, and a determination circuit 20d5.

The selector 20d1 can extract the image data 100 to be used as the determination object that is stored in the memory 20c.

The selector 20d2 can extract the “comparison data” that is stored in the comparison data memory 20c1.

The subtractor circuit 20d3 can determine the difference between the “comparison data” and the image data 100 to be used as the determination object.

The comparison circuit 20d4 can compare the value of the difference determined by the subtractor circuit 20d3 and the threshold stored in the memory 20c. For example, the value of the difference increases when the X-rays are incident because the values of the read image data 100 change. Therefore, the determination circuit 20d5 can determine that the X-ray incidence has not started if the value of the difference is less than the threshold, and can determine that the X-ray incidence has started when the value of the difference is greater than the threshold.

When determining that the X-ray incidence has started, the X-ray incidence determination circuit 20d can transmit, to the controller 20e, a signal indicating that the X-ray incidence has started.

The controller 20e can control the circuits of the circuit board 20 based on the control program stored in the memory 20c. For example, the controller 20e can control the gate drive circuit 20a and the signal detection circuit 20b based on the control program.

The image configuration circuit 20f can configure the X-ray image based on the image data 100 stored in the memory 20c. The image configuration circuit 20f can be located outside the X-ray detector 1. When the image configuration circuit 20f is located outside the X-ray detector 1, the data communication between the circuit board 20 and the image configuration circuit 20f can be performed via wiring, etc., or can be wireless. The image configuration circuit 20f can transmit the data of the configured X-ray image to a display device or another device located outside the X-ray detector 1.

The determination of the incidence start of the X-rays will now be described further.

As described above, the incidence start of the X-rays can be known by determining the difference between the “comparison data” and the image data 100 to be used as the determination object. Because it is difficult to predict the incidence timing of the X-rays, it is necessary to continuously acquire and compare the “comparison data” and the image data 100 to be used as the determination object. Therefore, it is necessary to constantly operate the X-ray incidence determination circuit 20d illustrated in FIG. 7. In such a case, by using data of one X-ray image, the X-ray incidence determination circuit 20d is substantially constantly operated due to the determination of the incidence start of the X-rays, and the power consumption is large even in standby when X-rays are not incident. Also, because a temperature increase due to heat generation occurs, there are cases where the use of the X-ray detector 1 is limited in a high-temperature environment. Also, a large-capacity comparison data memory 20c1 is necessary to store the “comparison data” of one X-ray image.

Therefore, in the X-ray detector 1 according to the embodiment, the gate drive circuit 20a and the signal detection circuit 20b are controlled by dividing the multiple control lines G into a first group and a second group that is next to the first group in the column direction. For example, the first group can be the multiple control lines G included in the “incidence detection region”. For example, the second group can be the multiple control lines G included in the “region in which the X-ray image is acquired”.

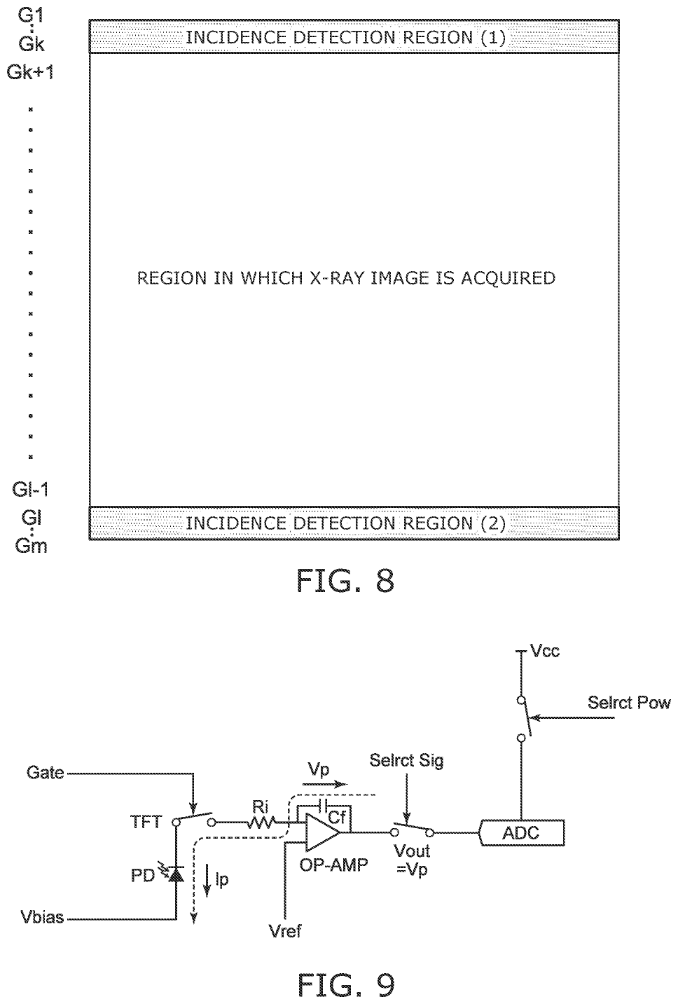

FIG. 8 is a schematic view for illustrating the “incidence detection region”.

The “incidence detection region” can be provided on at least one outer side of the “region in which the X-ray image is acquired” in the column direction. The “incidence detection region” illustrated in FIG. 8 is provided at both outer sides of the “region in which the X-ray image is acquired”.

According to knowledge obtained by the inventor, it is sufficient to include several (in FIG. 8, “k” or “m-l”) control lines G for the X-ray incidence detection. For example, it is sufficient to use 5% or less of all of the control lines G. When the invention is implemented in an existing X-ray detector, a portion of the multiple control lines G that is already provided can be used as the “incidence detection region”. In such a case, even if a portion of the multiple control lines G is used for only the “incidence detection region”, this portion is about several % of the entirety; therefore, the quality of the X-ray image is not drastically reduced. Although the image data of the “incidence detection region” is used to configure the peripheral edge portion of the X-ray image, it is extremely rare that an imaging object or an important imaging portion is in the peripheral edge portion of the X-ray image. Therefore, even if a portion of the multiple control lines G is used for only the “incidence detection region”, the risk of an unfavorable effect in diagnosis, etc., is low.

A portion of the multiple control lines G can be used for both the “incidence detection region” and the “region in which the X-ray image is acquired”. For example, when X-ray incidence is detected using the “incidence detection region”, the image data 100 is read from the “region in which the X-ray image is acquired”. The X-rays are also irradiated while the image data 100 is being read from the “region in which the X-ray image is acquired”; therefore, charge is again stored in the “incidence detection region”. Therefore, the image data 100 of one X-ray image can be read by reading the image data 100 from the “incidence detection region” after reading the image data 100 from the “region in which the X-ray image is acquired”.

When newly manufacturing an X-ray detector, the same number of control lines G as the existing X-ray detector can be provided, and similarly to the description described above, a portion of the control lines G can be used as the “incidence detection region”. Or, the control lines G that are used for only the “incidence detection region” can be increased. When the control lines G are increased, it is necessary to increase the photoelectric converters 2b, the data lines S, the gate drive circuits 20a, the signal detection circuits 20b, etc., connected to the increased control lines G; however, the amount of the increase is about several % of the entirety, and these components are collectively manufactured in the semiconductor manufacturing processes; therefore, hardware modifications or drastic cost increases do not occur.

As shown in FIG. 3, the switching between the reading of the image data 100 from the “incidence detection region” and the reading of the image data 100 from the “region in which the X-ray image is acquired” can be performed by adding a circuit for switching the power supply of the signal detection circuit 20b (the AD converter 20bc) ON/OFF.

FIG. 9 is an equivalent circuit considering the switching of the reading.

As shown in FIG. 9, a circuit for switching the power supply of the AD converter 20bc ON/OFF can be provided. Thus, the switching between the reading of the image data 100 from the “incidence detection region” and the reading of the image data 100 from the “region in which the X-ray image is acquired” can be performed.

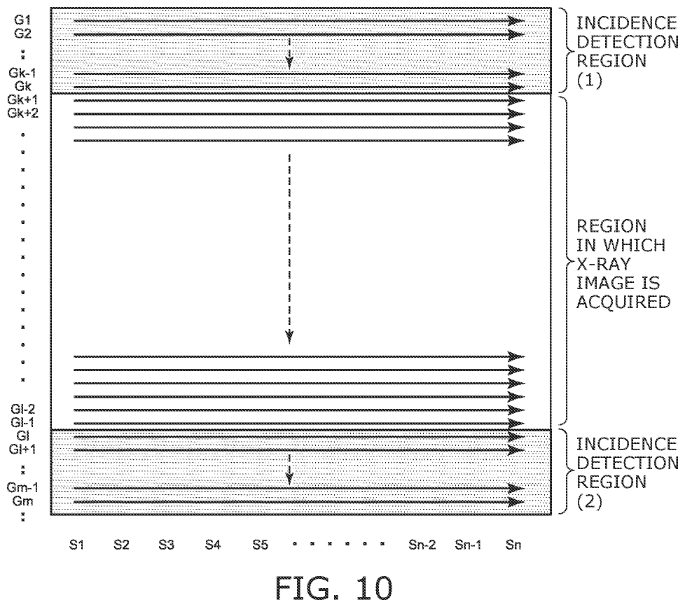

FIG. 10 is a sequence diagram for illustrating the switching of the reading of the image data 100.

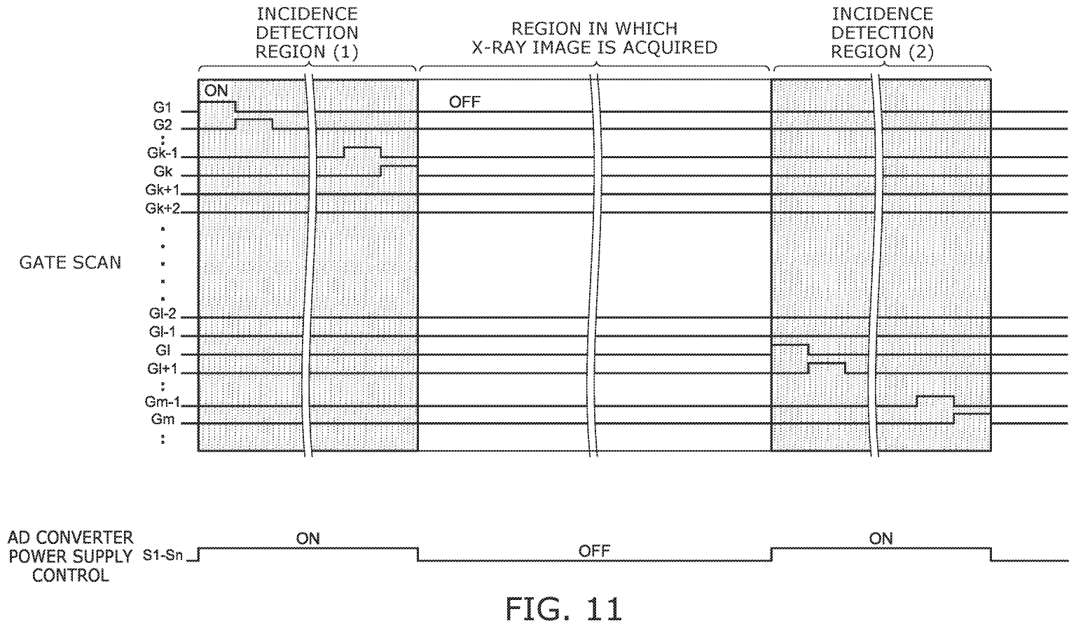

FIG. 11 is a timing chart for illustrating the reading of the image data 100 from the “incidence detection region”.

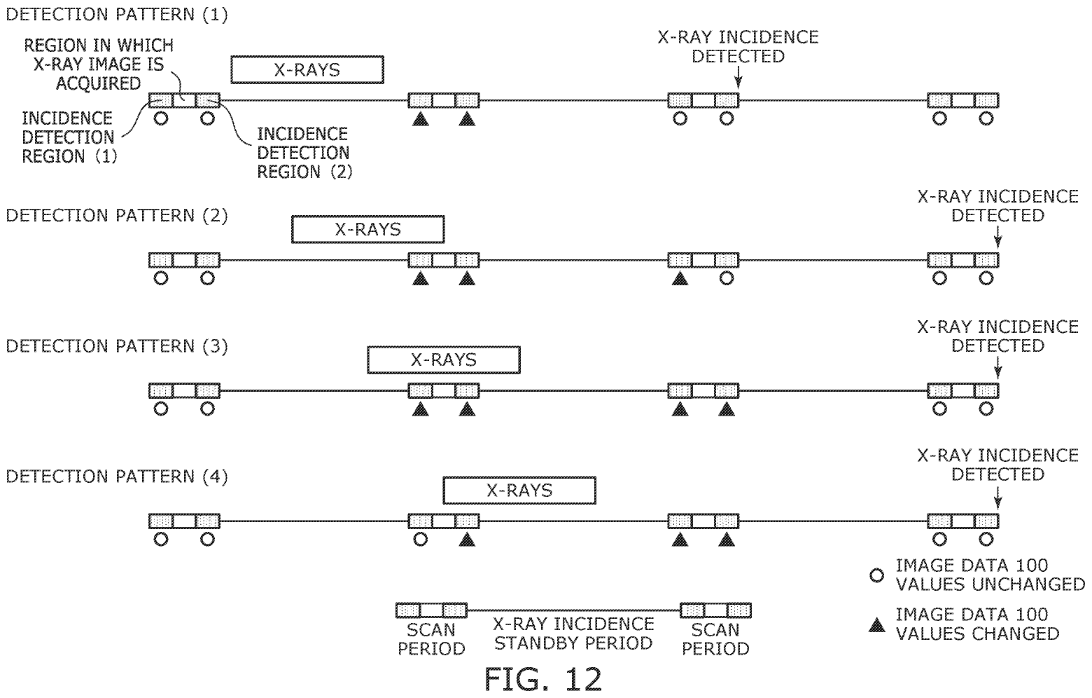

FIG. 12 is a schematic view for illustrating patterns of changes of the values of the image data 100.

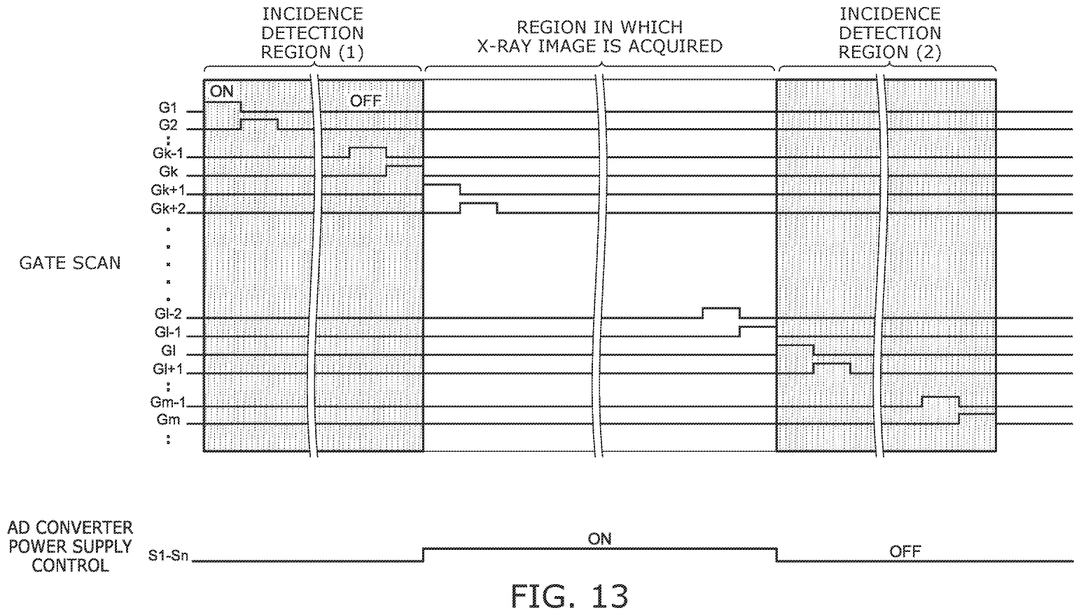

FIG. 13 is a timing chart for illustrating the reading of the image data 100 from the “region in which the X-ray image is acquired”.

As shown in FIG. 10, the reading of the image data 100 is performed sequentially (e.g., in order from the control line G1 in FIG. 10) for each of the multiple control lines G1 to Gm. For example, the reading of the image data 100 from the “incidence detection regions (1) and (2)” and the reading of the image data 100 from the “region in which the X-ray image is acquired” can be separated by performing time management.

In the state (the standby state) of detecting the X-ray incidence, as shown in the “incidence detection region (1)” of FIG. 11, the gate drivers 20aa are set to the ON-state for the scan start (the G1-line) to the scan end (the Gk-line), and the image data 100 can be read from the photoelectric converters 2b. At this time, the image data 100 can be read by setting the power supply of the AD converters 20bc to the ON-state;

therefore, the read image data 100 can be stored in the comparison data memory 20c1, and the comparison with the “comparison data” stored in the comparison data memory 20c1 can be performed.

In the state (the standby state) of detecting the X-ray incidence, the reading of the image data 100 from the “region in which the X-ray image is acquired” is not performed. Therefore, as shown in FIG. 11, the gate drivers 20aa are set to the OFF-state for the Gk+1 line to the G/−1 line. Because the charge that is stored in the photoelectric converters 2b is retained thereby, the quality of the X-ray image is not affected even when X-rays are input partway through the scan.

Because the reading of the image data 100 from the “region in which the X-ray image is acquired” is not performed, the power supply of the AD converters 20bc is set to the OFF-state, and it is unnecessary to perform photoelectric conversion or signal processing (acquiring the image data 100, storing the image data 100 in the comparison data memory 20c1, or comparing with the “comparison data”).

Also, in the state (the standby state) of detecting the X-ray incidence as shown in the “incidence detection region (2)” of FIG. 11, similarly to the “incidence detection region (1)”, the gate drivers 20aa are set to the ON-state for the G/-line to the Gm-line, and the image data 100 can be read from the photoelectric converters 2b. At this time, by setting the power supply of the AD converters 20bc to the ON-state, the image data 100 can be read; therefore, the read image data 100 can be stored in the comparison data memory 20c1, and the comparison with the “comparison data” stored in the comparison data memory 20c1 can be performed.

When there is no difference with the “comparison data” for both the detection in the “incidence detection region (1)” and the detection in the “incidence detection region (2)”, it is determined that there is no X-ray incidence; and the detection in the “incidence detection region (1)”, the detection in the “region in which the X-ray image is acquired”, and the detection in the “incidence detection region (2)” can be repeated. At this time, in the detection in the “region in which the X-ray image is acquired”, which accounts for nearly all of the scan time, the gate scan operation is not performed; therefore, the power consumption of the AD converters 20bc is zero, and arithmetic processing such as the comparison with the “comparison data”, etc., are not performed. Therefore, the power consumption in the state (the standby state) of detecting the X-ray incidence can be drastically reduced.

Here, although the detection in the “incidence detection region (1)”, the detection in the “region in which the X-ray image is acquired”, and the detection in the “incidence detection region (2)” are repeatedly performed in the X-ray incidence detection, the X-ray incidence timing is random; therefore, the timing of the incidence of the X-rays is not knowable.

Therefore, as shown in FIG. 12, four types of detection patterns by incidence timing occur.

A “detection pattern (1)” is when X-rays are incident between the detection in the “incidence detection region (2)” of a previous scan and the detection in the “incidence detection region (1)” of a subsequent scan. In such a case, charge is stored in the “incidence detection region (1)” and the “incidence detection region (2)”; therefore, in the subsequent scan, the values of the image data 100 detected in the “incidence detection region (1)” and the “incidence detection region (2)” are changed.

A “detection pattern (2)” is when X-rays are incident in the detection in the “incidence detection region (1)” of the subsequent scan. In such a case as well, charge is stored in the “incidence detection region (1)” and the “incidence detection region (2)”; therefore, the values of the image data 100 detected in the “incidence detection region (1)” and the “incidence detection region (2)” of the subsequent scan are changed. Also, the values of the image data 100 detected in the “incidence detection region (1)” are changed in the next subsequent scan because charge is again stored in the “incidence detection region (1)”. On the other hand, charge is not stored again in the “incidence detection region (2)”; therefore, the values of the image data 100 detected in the “incidence detection region (2)” are unchanged in the next subsequent scan.

A “detection pattern (3)” is when X-rays are incident in the detection in the “incidence detection region (1)” and the detection in the “incidence detection region (2)” of the subsequent scan. In such a case as well, charge is stored in the “incidence detection region (1)” and the “incidence detection region (2)”; therefore, the values of the image data 100 detected in the “incidence detection region (1)” and the “incidence detection regions (2)” are changed. Also, because charge is again stored in the “incidence detection region (1)” and the “incidence detection region (2)”, the values of the image data 100 detected in the “incidence detection region (1)” and the “incidence detection region (2)” are changed in the next subsequent scan.

A “detection pattern (4)” is when X-rays are incident in the detection in the “incidence detection region (2)” in the subsequent scan. In such a case, charge is stored in the “incidence detection region (2)”; therefore, the values of the image data 100 detected in the “incidence detection region (2)” are changed. Also, because charge is again stored in the “incidence detection region (1)” and the “incidence detection region (2)”, the values of the image data 100 detected in the “incidence detection region (1)” and the “incidence detection region (2)” are changed in the next subsequent scan.

In such a case, it can be determined that the X-ray incidence has started when any of “detection pattern (1)” to “detection pattern (4)” occurs. Also, as shown in FIG. 12, the incidence start of the X-rays can be determined by including the results of two previous scans. Thus, erroneous detection due to noise, vibrations, etc., can be suppressed.

When it is determined that X-ray incidence has started, the image data 100 can be read from the “region in which the X-ray image is acquired” as shown in FIG. 13. The image data 100 is not read from the “region in which the X-ray image is acquired” until the X-ray incidence is detected; therefore, the image data 100 can be read without loss from when the X-rays are incident.

As described above, the controller 20e performs the control by dividing the multiple control lines G into the first group and the second group that is next to the first group in the column direction. The X-ray incidence determination circuit 20d can determine the incidence start of the X-rays based on the values of the image data 100 read from the photoelectric converters 2b electrically connected to the control lines G included in the first group.

The controller 20e can set the thin film transistors 2b2 electrically connected to the control lines G included in the second group to the OFF-state until the incidence start of the X-rays is detected by the X-ray incidence determination circuit 20d.

The signal detection circuit 20b can include the AD converter 20bc that converts the read image data 100 into a digital signal. The controller 20e can set the power supply of the AD converters 20bc electrically connected to the control lines G included in the second group via the thin film transistors 2b2 and the data lines S to the OFF-state until the incidence start of the X-rays is detected by the X-ray incidence determination circuit 20d.

The controller 20e can stop the reading of the image data 100 from the photoelectric converters 2b electrically connected to the control lines G included in the second group until the incidence start of the X-rays is detected by the X-ray incidence determination circuit 20d.

The controller 20e can stop the calculations of the subtractor circuit 20d3 and the comparison circuit 20d4 relating to the image data 100 from the photoelectric converters 2b electrically connected to the control lines G included in the second group until the incidence start of the X-rays is detected by the X-ray incidence determination circuit 20d.

In the X-ray detector 1 according to the embodiment, the region used to detect the X-ray incidence is limited to a portion of the region in which the multiple photoelectric converters 2b are provided; therefore, the AD conversion by the AD converters 20bc, the storing of the image data 100, the range of the comparison processing, etc., can be reduced. The reading of the image data 100 from the “incidence detection region” and the reading of the image data 100 from the “region in which the X-ray image is acquired” can be controlled by the control signal 101 and the ON/OFF of the power supply of the AD converters 20bc. Therefore, this can be performed merely by controlling the timing without a large change to the configuration of the existing X-ray detector. This configuration can suppress the power consumption when detecting the X-ray incidence. Also, because the region used to detect the X-ray incidence is limited, the capacitance of the comparison data memory 20c1 also can be low.

An X-ray detector 1a according to another embodiment will now be described.

Similarly to the X-ray detector 1 illustrated in FIGS. 1 to 3, the X-ray detection module 10 and the circuit board 20 can be provided in the X-ray detector 1a.

The array substrate 2 and the scintillator 3 can be provided in the X-ray detection module 10.

The gate drive circuit 20a, the signal detection circuit 20b, the memory 20c, the X-ray incidence determination circuit 20d, the controller 20e, and the image configuration circuit 20f can be provided in the circuit board 20.

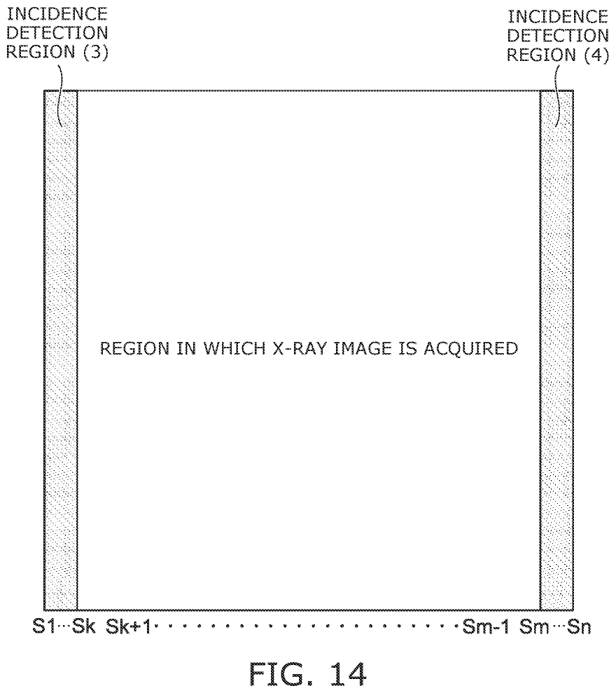

Here, in the X-ray detector 1a according to the embodiment, the control of the gate drive circuit 20a and the signal detection circuit 20b is performed by dividing the multiple data lines S into a third group and a fourth group that is next to the third group in the row direction. As shown in FIG. 14 described below, for example, the third group can be the multiple data lines S included in the “incidence detection region (3)”. For example, the fourth group can be the multiple data lines S included in the “incidence detection region (4) in which the X-ray image is acquired”.

FIG. 14 is a schematic view for illustrating the “incidence detection region”.

The “incidence detection region” can be provided on at least one outer side of the “region in which the X-ray image is acquired” in the row direction. The “incidence detection region” illustrated in FIG. 14 is provided at both outer sides of the “region in which the X-ray image is acquired”.

According to knowledge obtained by the inventor, it is sufficient to include several (in FIG. 14, “k” or “n-m”) data lines S for the X-ray incidence detection. For example, it is sufficient to use 5% or less of all of the data lines S. When the invention is implemented in an existing X-ray detector, a portion of the multiple data lines S that is already provided can be used as the “incidence detection region”. In such a case, even if a portion of the multiple data lines S is used for only the “incidence detection region”, this portion is about several % of the entirety; therefore, the quality of the X-ray image is not drastically reduced. Although the image data of the “incidence detection region” is used to configure the peripheral edge portion of the X-ray image, it is extremely rare that an imaging object or an important imaging portion is in the peripheral edge portion of the X-ray image. Therefore, even if a portion of the multiple data lines S is used for only the “incidence detection region”, the risk of an unfavorable effect in diagnosis, etc., is low.

A portion of the multiple data lines S can be used for both the “incidence detection region” and the “region in which the X-ray image is acquired”. For example, when the X-ray incidence is detected by using the “incidence detection region”, the image data 100 is read from the “region in which the X-ray image is acquired”. The X-rays are also irradiated while the image data 100 is being read from the “region in which the X-ray image is acquired”; therefore, charge is again stored in the “incidence detection region”. Therefore, the image data 100 of one X-ray image can be read by reading the image data 100 from the “incidence detection region” after reading the image data 100 from the “region in which the X-ray image is acquired”.

When newly manufacturing an X-ray detector, the same number of data lines S as the existing X-ray detector can be provided, and similarly to the description described above, a portion of the data lines S can be used as the “incidence detection region”. Or, the data lines S that are used for only the “incidence detection region” can be increased. When the data lines S are increased, it is necessary to increase the photoelectric converters 2b, the data lines S, the gate drive circuits 20a, the signal detection circuits 20b, etc., connected to the increased data lines S; however, the amount of the increase is about several % of the entirety, and these components are collectively manufactured in the semiconductor manufacturing processes; therefore, hardware modifications or drastic cost increases do not occur.

As illustrated in FIG. 3 described above, the switching between the reading of the image data 100 from the “incidence detection region” and the reading of the image data 100 from the “region in which the X-ray image is acquired” can be performed by adding a circuit for switching the power supply of the signal detection circuit 20b (the AD converter 20bc) ON/OFF.

The equivalent circuit considering the switching of the reading can be similar to the equivalent circuit illustrated in FIG. 9.

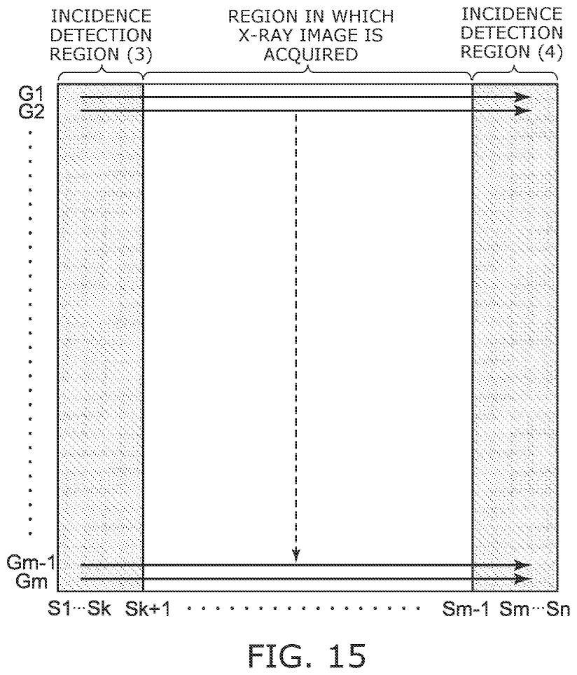

FIG. 15 is a sequence diagram for illustrating the switching of the reading of the image data 100.

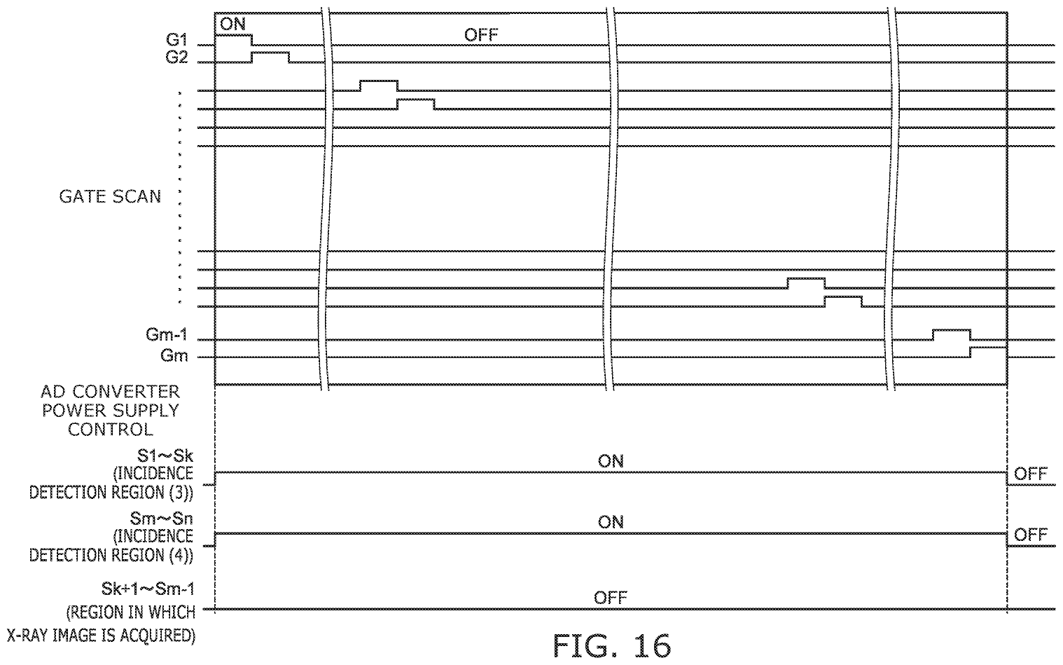

FIG. 16 is a timing chart for illustrating the reading of the image data 100 from the “incidence detection region”.

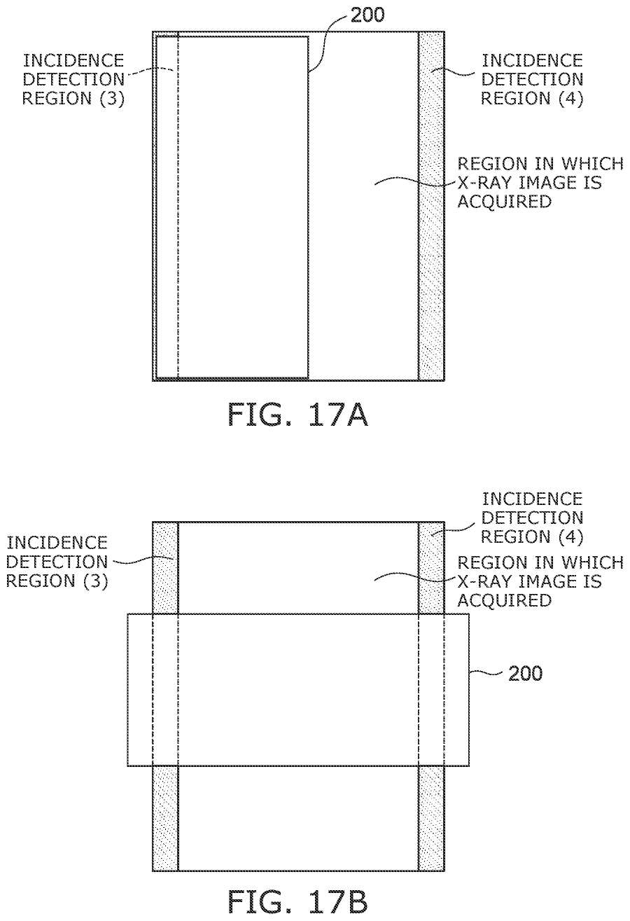

FIGS. 17A and 17B are schematic views for illustrating the relationship between the “incidence detection region” and the position of a subject 200.

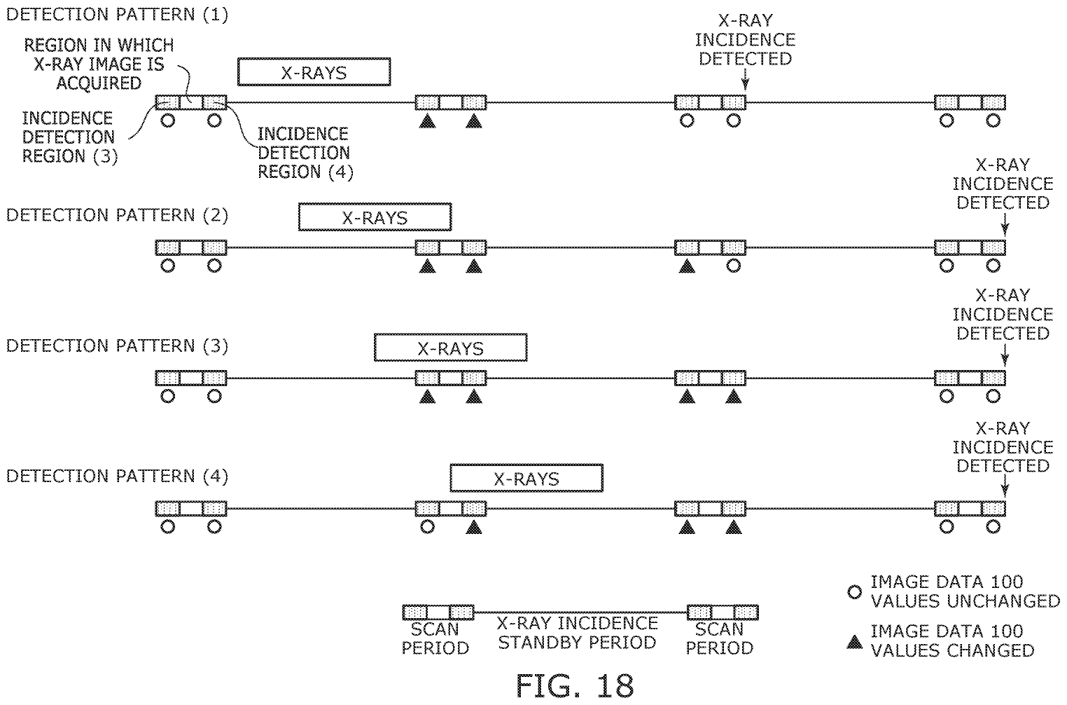

FIG. 18 is a schematic view for illustrating patterns of changes of the values of the image data 100.

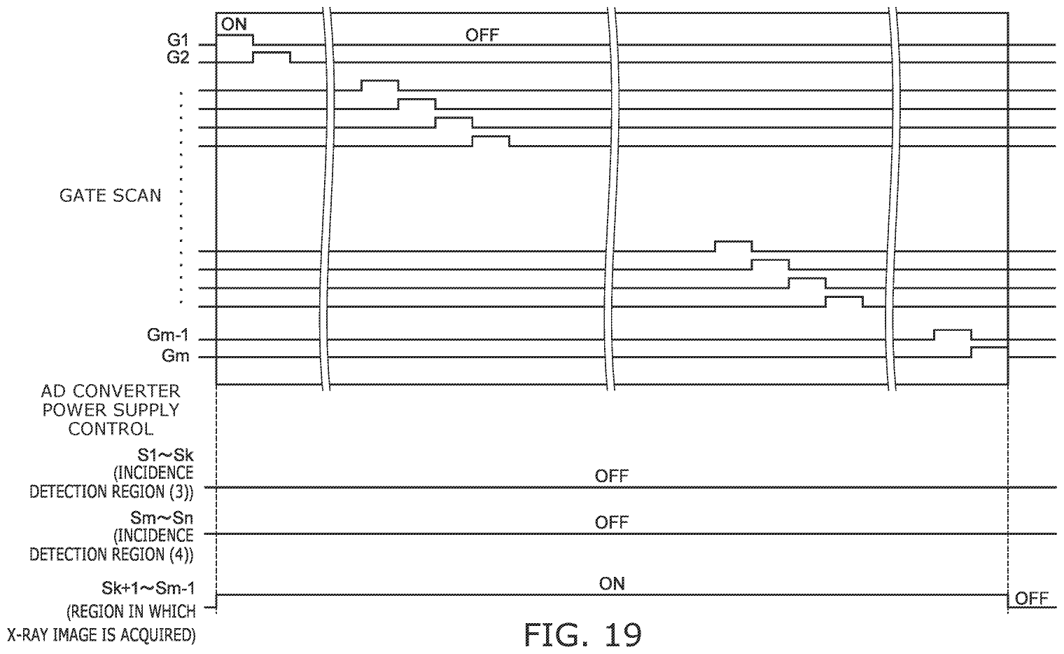

FIG. 19 is a timing chart for illustrating the reading of the image data 100 from the “region in which the X-ray image is acquired”.

As shown in FIG. 15, the reading of the image data 100 is performed sequentially (e.g., in order from the control line G1 in FIG. 15) for each of the multiple control lines G1 to Gm. For example, the reading of the image data 100 from the “incidence detection region (3)” and the “incidence detection region (4)” can be performed by reading the image data 100 from the data lines S1 to Sk and the data lines Sm to Sn. The reading of the image data 100 from the “region in which the X-ray image is acquired” can be performed by reading the image data 100 from the data lines Sk+1 to Sm−1.

In the state (the standby state) of detecting the X-ray incidence, as shown in the “incidence detection region (3)” and the “incidence detection region (4)” of FIG. 16, the power supply of the signal detection circuits 20b (the AD converters 20bc) is set to the ON-state for the data lines S1 to Sk and the data lines Sm to Sn, and the image data 100 is read from the photoelectric converters 2b. The read image data 100 can be stored in the comparison data memory 20c1, and the comparison between the read image data 100 and the “comparison data” stored in the comparison data memory 20c1 can be performed. Although an example is illustrated in which the image data 100 is read from the data lines S1 to Sk and the data lines Sm to Sn, the image data 100 may be read from one of the data lines S1 to Sk or the data lines Sm to Sn.

Here, when the “incidence detection region” is covered with the subject 200, the X-rays are absorbed by the subject 200 and do not easily reach the “incidence detection region”. Therefore, there is a risk that the accuracy of the X-ray incidence detection may decrease according to the position of the subject 200.

In such a case, if the reading of the image data 100 from the “incidence detection region (3)” and the “incidence detection region (4)” is performed, even if one of the “incidence detection region (3)” or the “incidence detection region (4)” is covered with the subject 200 as illustrated in FIG. 17A, the other of the “incidence detection region (3)” or the “incidence detection region (4)” is easily exposed outside the subject 200. Therefore, the reduction of the accuracy of the X-ray incidence detection can be suppressed. In FIG. 17A, the “incidence detection region (3)” is covered with the subject 200, and the “incidence detection region (4)” is exposed outside the subject 200.

As illustrated in FIG. 17B, even if portions of the “incidence detection region (3)” and the “incidence detection region (4)” are covered with the subject 200, the remaining portions of the “incidence detection region (3)” and the “incidence detection region (4)” are easily exposed outside the subject 200. Therefore, the reduction of the accuracy of the X-ray incidence detection can be suppressed.

In the state (the standby state) of detecting the X-ray incidence, the reading of the image data 100 from the “region in which the X-ray image is acquired” is not performed. Therefore, as shown in FIG. 16, the power supply of the signal detection circuits 20b (the AD converters 20bc) is set to the OFF-state for the data lines Sk+1 to Sm−1. Because the charge that is stored in the photoelectric converters 2b is retained thereby, the quality of the X-ray image is not affected even when X-rays are input partway through the scan. Because the reading of the image data 100 from the “region in which the X-ray image is acquired” is not performed, it is unnecessary to perform photoelectric conversion or signal processing (acquiring the image data 100, storing the image data 100 in the comparison data memory 20c1, or comparing with the “comparison data”).

When there is no difference with the “comparison data” for both the detection in the “incidence detection region (3)” and the detection in the “incidence detection region (4)”, it is determined that there is no X-ray incidence, and the detection in the “incidence detection region (3)” and the detection in the “incidence detection region (4)” can be repeated. At this time, the power supply of the signal detection circuits 20b (the AD converters 20bc) is set to the OFF-state in the detection in the “region in which the X-ray image is acquired”, which includes nearly all of the photoelectric converters 2b, and arithmetic processing such as the comparison with the “comparison data”, etc., are not performed. Therefore, the power consumption in the state (the standby state) of detecting the X-ray incidence can be drastically reduced.

Here, although the detection in the “incidence detection region (3)” and the detection in the “incidence detection region (4)” are repeatedly performed in the X-ray incidence detection, the X-ray incidence timing is random; therefore, the timing of the incidence of the X-rays is not knowable.

Therefore, as shown in FIG. 18, four types of detection patterns by incidence timing occur.

The “detection pattern (1)” is when X-rays are incident between the detection in the “incidence detection region (4)” of a previous scan and the detection in the “incidence detection region (3)” of a subsequent scan. In such a case, charge is stored in the “incidence detection region (3)” and the “incidence detection region (4)”; therefore, in the subsequent scan, the values of the image data 100 detected in the “incidence detection region (3)” and the “incidence detection region (4)” are changed.

The “detection pattern (2)” is when X-rays are incident in the detection in the “incidence detection region (3)” of the subsequent scan. In such a case as well, charge is stored in the “incidence detection region (3)” and the “incidence detection region (4)”; therefore, the values of the image data 100 detected in the “incidence detection region (3)” and the “incidence detection region (4)” of the subsequent scan are changed. Also, the values of the image data 100 detected in the “incidence detection region (3)” are changed in the next subsequent scan because charge is again stored in the “incidence detection region (3)”. On the other hand, charge is not stored again in the “incidence detection region (4)”; therefore, the values of the image data 100 detected in the “incidence detection region (4)” are unchanged in the next subsequent scan.

The “detection pattern (3)” is when X-rays are incident in the detection in the “incidence detection region (3)” and the detection in the “incidence detection region (4)” of the subsequent scan. In such a case as well, charge is stored in the “incidence detection region (3)” and the “incidence detection region (4)”; therefore, the values of the image data 100 detected in the “incidence detection region (3)” and the incidence detection regions (4)” are changed. Also, because charge is again stored in the “incidence detection region (3)” and the “incidence detection region (4)”, the values of the image data 100 detected in the “incidence detection region (3)” and the “incidence detection region (4)” are changed in the next subsequent scan.

The “detection pattern (4)” is when X-rays are incident in the detection in the “incidence detection region (4)” in the subsequent scan. In such a case, charge is stored in the “incidence detection region (4)”; therefore, the values of the image data 100 detected in the “incidence detection region (4)” are changed. Also, because charge is again stored in the “incidence detection region (3)” and the “incidence detection region (4)”, the values of the image data 100 detected in the “incidence detection region (3)” and the “incidence detection region (4)” are changed in the next subsequent scan.

In such a case, it can be determined that the X-ray incidence has started when any of the “detection pattern (1)” to the “detection pattern (4)” occurs. Also, as shown in FIG. 18, the incidence start of the X-rays can be determined by including the results of two previous scans. Thus, erroneous detection due to noise, vibrations, etc., can be suppressed.

When it is determined that X-ray incidence has started, the image data 100 can be read from the “region in which the X-ray image is acquired” as shown in FIG. 19. The image data 100 is not read from the “region in which the X-ray image is acquired” until the X-ray incidence is detected; therefore, the image data 100 can be read without loss from when the X-rays are incident.

As described above, the controller 20e performs the control by dividing the multiple data lines S into the third group and the fourth group that is next to the third group in the column direction. The X-ray incidence determination circuit 20d can determine the incidence start of the X-rays based on the values of the image data 100 read from the photoelectric converters 2b electrically connected to the data lines S included in the third group.

The controller 20e can set the power supply of the signal detection circuits 20b (the AD converters 20bc) electrically connected to the data lines S included in the fourth group to the OFF-state until the incidence start of the X-rays is detected by the X-ray incidence determination circuit 20d.

The controller 20e can stop the reading of the image data 100 from the photoelectric converters 2b electrically connected to the data lines S included in the fourth group until the incidence start of the X-rays is detected by the X-ray incidence determination circuit 20d.

The controller 20e can stop the calculations of the subtractor circuit 20d3 and the comparison circuit 20d4 relating to the image data 100 from the photoelectric converters 2b electrically connected to the data lines S included in the fourth group until the incidence start of the X-rays is detected by the X-ray incidence determination circuit 20d.

The controller 20e can set the thin film transistors 2b2 electrically connected to the data lines S included in the fourth group to the OFF-state until the incidence start of the X-rays is detected by the X-ray incidence determination circuit 20d.

In the X-ray detector 1a according to the embodiment, the region used to detect the X-ray incidence is limited to a portion of the region in which the multiple photoelectric converters 2b are provided; therefore, the AD conversion by the AD converters 20bc, the storing of the image data 100, the range of the comparison processing, etc., can be reduced. The reading of the image data 100 from the “incidence detection region” and the reading of the image data 100 from the “region in which the X-ray image is acquired” can be controlled by the control signal 101 and the ON/OFF of the power supply of the AD converters 20bc. Therefore, this can be performed merely by controlling the timing without a large change to the configuration of the existing X-ray detector. This configuration can suppress the power consumption when detecting the X-ray incidence. Also, because the region used to detect the X-ray incidence is limited, the capacitance of the comparison data memory 20c1 also can be low.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the formation of the embodiments described herein may be made without departing from the spirit of the inventions. The accompanying claims and their equivalents are intended to cover such forms or modifications as would fall within the scope and spirit of the inventions. Moreover, the above-mentioned embodiments can be combined mutually and can be carried out.

What is claimed is:

1. A radiation detector, comprising:
a plurality of control lines extending in a first direction, the plurality of control lines being arranged in a second direction crossing the first direction;
a plurality of data lines extending in the second direction, the plurality of data lines being arranged in the first direction;
a plurality of detecting parts detecting radiation directly or in collaboration with a scintillator, each of the plurality of detecting parts including a thin film transistor electrically connected to a corresponding control line of the plurality of control lines and a corresponding data line of the plurality of data lines;
a gate drive circuit switching between an ON-state and an OFF-state of the thin film transistors;
a signal detection circuit reading image data from the detecting parts when the thin film transistors are in the ON-state;
a radiation incidence determination circuit determining an incidence start of the radiation based on a value of the read image data; and
a controller controlling the gate drive circuit and the signal detection circuit,
the controller performing the control by dividing the plurality of control lines into a first group and a second group, and the radiation incidence determination circuit determining the incidence start of the radiation based on a value of the image data read from the detecting part electrically connected to the control line included in the first group, the second group being next to the first group in the second direction, or
the controller performing the control by dividing the plurality of data lines into a third group and a fourth group, and the radiation incidence determination circuit determining the incidence start of the radiation based on a value of the image data read from the detecting part electrically connected to the data line included in the third group, the fourth group being next to the third group in the first direction.

2. The detector according to claim 1, wherein
the controller sets the thin film transistors electrically connected to the control line included in the second group to the OFF-state until the incidence start of the radiation is detected by the radiation incidence determination circuit.

3. The detector according to claim 1, wherein
the signal detection circuit includes an AD converter converting the read image data into a digital signal, and
the controller sets, to the OFF-state, a power supply of the AD converter electrically connected to the control line included in the second group via the thin film transistor and the data line until the incidence start of the radiation is detected by the radiation incidence determination circuit.

4. The detector according to claim 1, wherein
the controller stops a reading of the image data from the detecting part electrically connected to the control line included in the second group until the incidence start of the radiation is detected by the radiation incidence determination circuit.

5. The detector according to claim 1, wherein
the radiation incidence determination circuit includes:
a subtractor circuit determining a difference between comparison data and the image data to be used as a determination object; and
a comparison circuit determining the incidence start of the radiation by comparing a threshold and a value of the difference determined by the subtractor circuit, and
the controller stops calculations of the subtractor circuit and the comparison circuit relating to the image data from the detecting part electrically connected to the control line included in the second group until the incidence start of the radiation is detected by the radiation incidence determination circuit.

6. The detector according to claim 5, wherein
the comparison data is image data read directly before the image data to be used as the determination object.

7. The detector according to claim 6, further comprising:
memory temporarily storing the comparison data.

8. The detector according to claim 1, wherein
the first group is provided on at least one outer side of the second group in the second direction.

9. The detector according to claim 1, wherein
a number of the control lines included in the first group is 5% or less of a total number of the control lines.

10. The detector according to claim 1, wherein
the controller reads the image data from the detecting part electrically connected to the control line included in the second group after the incidence start of the radiation is detected by the radiation incidence determination circuit, and subsequently reads the image data from the detecting part electrically connected to the control line included in the first group.

11. The detector according to claim 1, wherein
the controller sets, to the OFF-state, the thin film transistors electrically connected to the data line included in the fourth group until the incidence start of the radiation is detected by the radiation incidence determination circuit.

12. The detector according to claim 1, wherein
the signal detection circuit includes an AD converter converting the read image data into a digital signal, and
the controller sets, to the OFF-state, a power supply of the AD converter electrically connected to the data line included in the fourth group until the incidence start of the radiation is detected by the radiation incidence determination circuit.

13. The detector according to claim 1, wherein
the controller stops a reading of the image data from the detecting part electrically connected to the data line included in the fourth group until the incidence start of the radiation is detected by the radiation incidence determination circuit.

14. The detector according to claim 1, wherein
the radiation incidence determination circuit includes:
a subtractor circuit determining a difference between comparison data and the image data to be used as a determination object; and
a comparison circuit determining the incidence start of the radiation by comparing a threshold and a value of the difference determined by the subtractor circuit, and
the controller stops calculations of the subtractor circuit and the comparison circuit relating to the image data from the detecting part electrically connected to the data line included in the fourth group until the incidence start of the radiation is detected by the radiation incidence determination circuit.

15. The detector according to claim 14, wherein
the comparison data is image data read directly before the image data to be used as the determination object.

16. The detector according to claim 15, further comprising:
memory temporarily storing the comparison data.

17. The detector according to claim 1, wherein
the third group is provided on at least one outer side of the fourth group in the first direction.

18. The detector according to claim 1, wherein
a number of the data lines included in the third group is 5% or less of a total number of the data lines.

19. The detector according to claim 1, wherein
the controller reads the image data from the detecting part electrically connected to the data line included in the fourth group after the incidence start of the radiation is detected by the radiation incidence determination circuit, and subsequently reads the image data from the detecting part electrically connected to the data line included in the third group.

20. The detector according to claim 1, wherein
the scintillator includes a plurality of columnar crystals.
